(19) United States
(12) Patent Application Publication
(10) Pub. No.: US 2008/0024164 A1
(43) Pub. Date: Jan. 31, 2008

(54) Reconfigurable programmable logic device with P-channel non-volatile memory cells

(75) Inventors: Hsiang-Tai Lu, Hsinchu (TW); Cheng-Hsiung Kuo, Hsinchu (TW); Yue-Der Chih, Hsinchu (TW)

Correspondence Address: L. Howard Chen, Esq.;Kirkpatrick & Lockhart Preston Gates Ellis LLP, Suite 1700, 55 Second Street, San Francisco, CA, 94104, US

(73) Assignee: Taiwan Semiconductor Manufacturing Co., Ltd.

(21) Appl. No.: 11/496,254

(22) Filed: Jul. 31, 2006

(51) Int. Cl. H03K 19/177

(52) U.S. Cl. 326/40

(57) ABSTRACT

A system is disclosed for constructing a reconfigurable programmable logic device (PLD) comprising a first P-channel nonvolatile memory cell with a first source, a first drain and a first gate coupled to a first input node, a second P-channel nonvolatile memory cell with a second source, a second drain and a second gate coupled to a second input node, and an NMOS transistor with a third source and a third drain, wherein the first and second sources are commonly connected to a positive voltage supply (Vcc), the first, second and third drains are commonly connected to an output node and the third source is coupled to a complementary low voltage supply (Vss).

### BACKGROUND

The present invention relates generally to semiconductor devices, and more particularly to a reconfigurable programmable logic device.

A programmable logic device (PLD) is a semiconductor device that offers a collection of various types of logic gates and some interconnections. This is essentially the opposite of a custom-tailored integrated circuit (IC), which is often justified for high volume applications but impractical if bulk production is not necessary. However, applications that do not command large volumes to justify highly custom-tailored solutions nevertheless need at least some degree of customization capabilities, which allow the customer to save design time.

For the purpose of customization, software is often given to customers who want and need to program the PLD devices. By utilizing various philosophies of organization, the software seeks an optimized logic layout.

An effective mechanism for programming logic functions is the use of erasable or electrically erasable programmable read only memories, EPROMs or EEPROMs. These non-volatile devices allow at any convenient time the insertion of logic states or connections. These logic states or connections have a very long lifetime, and can be reprogrammed into new logic states that will also have a long lifetime. Programming such devices at each power start-up, however, has required added external memory circuitry, which can be uneconomical in the increasingly commoditized semiconductor market.

It is thus desirable to use non-volatile memory cells, such as P-channel EEPROMs to form a PLD.

### SUMMARY

In view of the foregoing, the following provides an array construction of a reconfigurable programmable logic device (PLD).

In one embodiment, the reconfigurable PLD comprises a first P-channel nonvolatile memory cell with a first source, a first drain and a first gate coupled to a first input node, a second P-channel nonvolatile memory cell with a second source, a second drain and a second gate coupled to a second input node, and a NMOS transistor with a third source and a third drain, wherein the first and second sources are commonly connected to a positive voltage supply (Vcc), the first, second and third drains are commonly connected to an output node and the third source is coupled to a complementary low voltage supply (Vss).

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1A is a cross-sectional view of an N-channel EEPROM cell structure.

FIG. 1B is a cross-sectional view of a P-channel EEPROM cell structure.

FIG. 2A is a schematic diagram of a part of a PLD array formed by N-channel EEPROM cells.

FIG. 2B is a schematic diagram of an equivalent circuit of the part of PLD array shown in FIG. 2A.

FIG. 3A is a schematic diagram of a part of a PLD array formed by P-channel EEPROM cells according to one embodiment of the present invention.

FIG. 3B is a schematic diagram of an equivalent circuit of the part of PLD array shown in FIG. 3A.

### DESCRIPTION

The following will provide a detailed description of a reconfigurable programmable logic device (PLD) formed by P-channel EEPROM cells. But as a background knowledge, a PLD formed by conventional N-channel EEPROM cells is first discussed.

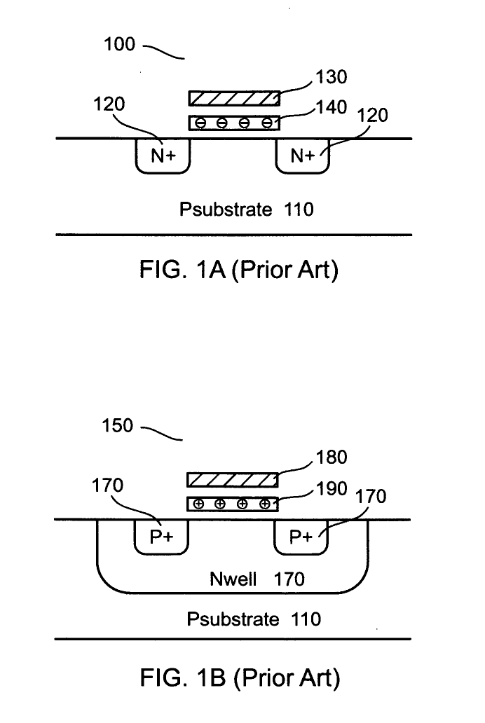

FIG. 1A is a cross-sectional view of an N-channel EEPROM cell structure 100. The N-channel EEPROM cell 100 is formed inside a P-substrate 110, with N+ source and drain 120. Between a gate 130 and the P-substrate 110, there is a floating gate 140 that can permanently store charges. As shown in FIG. 1A, when negative charges are stored in the floating gate 140, a threshold voltage (Vt) of the N-channel EEPROM cell 100 will be increased, i.e., being programmed, so that the N-channel EEPROM cell 100 will essentially be permanently switched off during normal operation. When in eased, i.e. low Vt state, the N-channel EEPROM cell behaves just like a regular N-type metal-semiconductor-oxide (NMOS) transistor.

FIG. 1B is a cross-sectional view of a P-channel EEPROM cell structure 150. The P-channel EEPROM cell 150 is formed inside a Nwell 160, which in turn is formed inside the P-substrate 110. A source and drain of the P-channel EEPROM cell 160 is formed by P+ 170. Between a gate 180 and the Nwell 160, there is a floating gate 190 that can permanently store charges. As shown in FIG. 1B, when positive charges are stored in the floating gate 190, the absolute value of a threshold voltage (|Vt|) of the P-channel EEPROM 150 will be increased, i.e., being programmed, so that the P-channel EEPROM cell 150 will essentially be permanently switched off during normal operation. When in eased, i.e. low |Vt| state, the P-channel EEPROM cell behaves just like a regular P-type metal-semiconductor-oxide (PMOS) transistor.

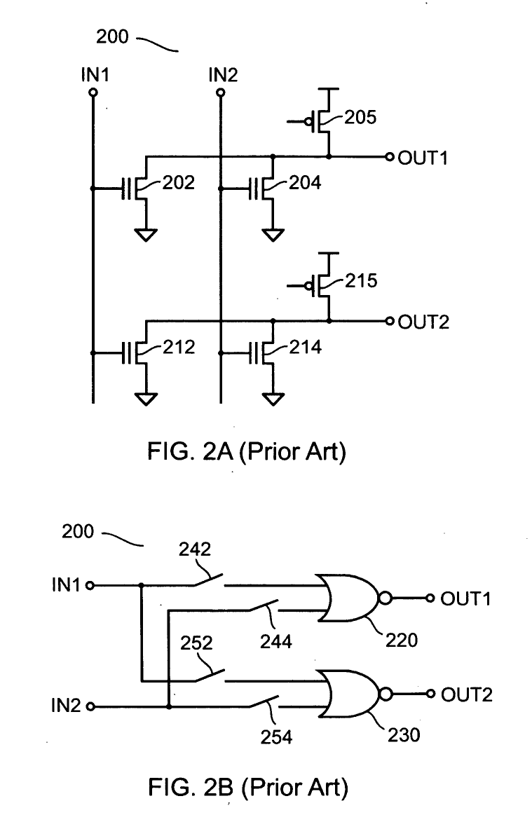

FIG. 2A is a schematic diagram of a part of a PLD array 200 formed by N-channel EEPROM cells 202, 204, 212 and 214, along with regular PMOS transistors 205 and 215. The following TABLE 1 summarizes various logic functions that can be achieved with this exemplary PLD array 200 through either programming or erasing the N-channel EEPROM cells 202, 204, 212 and 214. Note that (X)′ stands for complementary of X.

TABLE 1

| 202 | 204 | 212 | 214 | OUT1 | OUT2 |
|---|---|---|---|---|---|
| Erased | Erased | Erased | Erased | (IN1 + IN2)′ | (IN1 + IN2)′ |
| Erased | Programmed | Erased | Programmed | (IN1)′ | (IN1)′ |
| Programmed | Erased | Programmed | Erased | (IN2)′ | (IN2)′ |
| Programmed | Programmed | Programmed | Programmed | No function | No function |

FIG. 2B is a schematic diagram of an equivalent circuit of the part of PLD array 200 shown in FIG. 2A. The equivalent circuit comprises two NOR gates 220 and 230. The N-channel EEPROM cells are represented by switches, i.e., switch 242 for cell 202, switch 244 for cell 204, switch 252 for cell 212 and switch 254 for cell 214. When a cell is programmed, its representative switch is open. When a cell is erased, then its representative switch is closed.

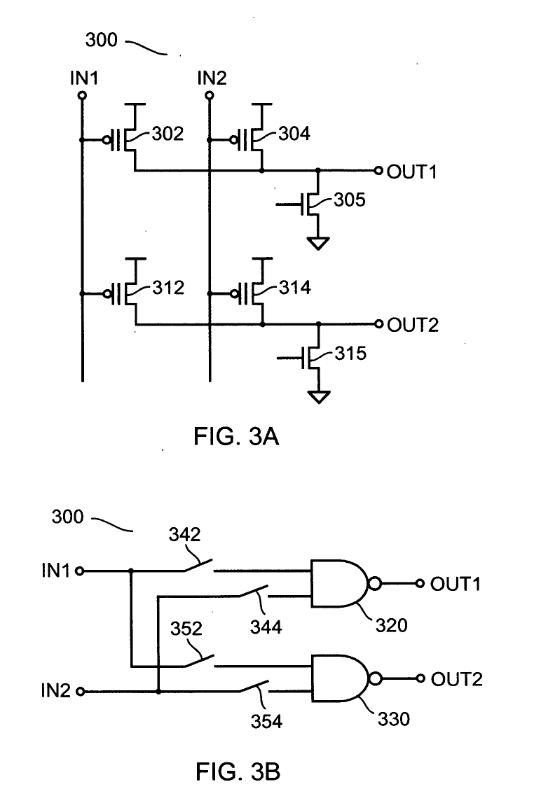

FIG. 3A is a schematic diagram of a part of a PLD array 300 formed by P-channel EEPROM cells 302, 304, 312 and 314, along with regular NMOS transistors 305 and 315, according to one embodiment of the present invention. Referring to FIG. 3A, sources of cells 302 and 304 are connected to a positive supply voltage (Vcc), and drains of the cells 302 and 304 are commonly connected to a drain of the NMOS transistor 305, while a source of the NMOS transistor 305 is connected to a complementary low supply voltage (Vss). So the cells 302 and 304 and the NMOS 305 form a two-input NAND gate with nodes IN1 and IN2 as inputs and a node OUT1 as a output. In a large PLD array, the nodes IN1 and IN2 represent bit-lines.

Similarly, cells 312 and 314 and the NMOS transistor 315 are connected also as a two-input NAND gate. Following TABLE 2 summarizes various logic functions that can be achieved with this exemplary PLD array 300 through either programming or erasing the P-channel EEPROM cells 302, 304, 312 and 314.

TABLE 2

| 302 | 304 | 312 | 314 | OUT1 | OUT2 |
|---|---|---|---|---|---|
| Erased | Erased | Erased | Erased | (IN1 · IN2)′ | (IN1 · IN2)′ |
| Erased | Programmed | Erased | Programmed | (IN1)′ | (IN1)′ |
| Programmed | Erased | Programmed | Erased | (IN2)′ | (IN2)′ |
| Programmed | Programmed | Programmed | Programmed | No function | No function |

FIG. 3B is a schematic diagram of an equivalent circuit of the part of PLD array 300 shown in FIG. 3A. The equivalent circuit comprises two NAND gates 320 and 330. The P-channel EEPROM cells are represented by switches, i.e., switch 342 for cell 302, switch 344 for cell 304, switch 352 for cell 312 and switch 354 for cell 314. When a cell is programmed, its representative switch is open. When a cell is erased, then its representative switch is closed.

Note that the exemplary PLD array 300 shown in FIGS. 3A and 3B can be expanded to more than two NAND gates connected to a bit-line, and each NAND gate can have more than two inputs, which means additional cells along with their corresponding bit-lines can be connected in parallel with the cells 302 and 304. The number of parallel cells equals the number of inputs of the NAND gates.

Because the P-channel EEPROM cells can be programmed and erased multiple times, so that the PLD formed by these cells can be reconfigured out in the field.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A reconfigurable programmable logic device (PLD) comprising:
a first P-channel nonvolatile memory cell with a first source, a first drain and a first gate coupled to a first input node;
a second P-channel nonvolatile memory cell with a second source, a second drain and a second gate coupled to a second input node; and
a NMOS transistor with a third source and a third drain,
wherein the first and second sources are commonly connected to a positive voltage supply (Vcc), the first, second and third drains are commonly connected to an output node and the third source is coupled to a complementary low voltage supply (Vss).

2. The reconfigurable PLD of claim 1, wherein both the first and the second P-channel nonvolatile memory cell are electrically erasable programmable read only memory (EEPROM) cells.

3. The reconfigurable PLD of claim 1, wherein
the first node is connected to a first bit-line to which a first plurality of P-channel nonvolatile memory cells are connected; and
the second node is connected to a second bit-line to which a second plurality of P-channel nonvolatile memory cells are connected.

4. The reconfigurable PLD of claim 3, wherein the first or second plurality of P-channel nonvolatile memory cells are an electrically erasable programmable read only memory (EEPROM) cells.

5. The reconfigurable PLD of claim 3, wherein
the first plurality of P-channel nonvolatile memory cells are identical to the first P-channel nonvolatile memory cell; and
the second plurality of P-channel nonvolatile memory cells are identical to the second P-channel nonvolatile memory cell.

6. The reconfigurable PLD of claim 2, wherein the first and second P-channel EEPROM cells and the NMOS transistor forms an NAND gate with the first and second input nodes as inputs and the output node as an output when both the first and second EEPROM cells are erased.

7. The reconfigurable PLD of claim 2, wherein the first P-channel EEPROM cell and the NMOS transistor form an inverter with the first input node as an input and the output node as an output when the first P-channel EEPROM cell is erased while the second P-channel EEPROM cell is programmed.

8. The reconfigurable PLD of claim 2, wherein the second P-channel EEPROM cell and the NMOS transistor form an inverter with the second input node as an input and the output node as an output when the second P-channel EEPROM cell is erased while the first P-channel EEPROM cell is programmed.

9. A reconfigurable programmable logic device (PLD) comprising:
a first P-channel EEPROM cell with a first source, a first drain and a first gate coupled to a first input node;
a second P-channel EEPROM cell with a second source, a second drain and a second gate coupled to a second input node; and
a NMOS transistor with a third source and a third drain,
wherein the first and second sources are commonly connected to a positive voltage supply (Vcc), the first, second and third drains are commonly connected to an output node and the third source is coupled to a complementary low voltage supply (Vss).

10. The reconfigurable PLD of claim 9, wherein
the first node is connected to a first bit-line to which a first plurality of P-channel EEPROM cells are connected; and
the second node is connected to a second bit-line to which a second plurality of P-channel EEPROM cells are connected.

11. The reconfigurable PLD of claim 10, wherein
the first plurality of P-channel EEPROM cells are identical to the first P-channel EEPROM cell; and
the second plurality of P-channel EEPROM cells are identical to the second P-channel EEPROM cell.

12. The reconfigurable PLD of claim 9, wherein the first and second P-channel EEPROM cells and the NMOS transistor forms an NAND gate with the first and second input nodes as inputs and the output node as an output when both the first and second EEPROM cells are erased.

13. The reconfigurable PLD of claim 9, wherein the first P-channel EEPROM cell and the NMOS transistor form an inverter with the first input node as an input and the output node as an output when the first P-channel EEPROM cell is erased while the second P-channel EEPROM cell is programmed.

14. The reconfigurable PLD of claim 9, wherein the second P-channel EEPROM cell and the NMOS transistor form an inverter with the second input node as an input and the output node as an output when the second P-channel EEPROM cell is erased while the first P-channel EEPROM cell is programmed.

15. A reconfigurable programmable logic device (PLD) comprising:
a first P-channel EEPROM cell with a first source, a first drain and a first gate coupled to a first bit-line to which a first plurality of P-channel EEPROM cells identical to the first P-channel EEPROM cell are connected;
a second P-channel EEPROM cell with a second source, a second drain and a second gate coupled to a second bit-line to which a second plurality of P-channel EEPROM cells identical to the second P-channel EEPROM are connected; and
an NMOS transistor with a third source and a third drain,
wherein the first and second sources are commonly connected to a positive voltage supply (Vcc), the first, second and third drains are commonly connected to an output node and the third source is coupled to a complementary low voltage supply (Vss).

16. The reconfigurable PLD of claim 15, wherein the first and second P-channel EEPROM cells and the NMOS transistor forms an NAND gate with the first and second bit-lines as inputs and the output node as an output when both the first and second EEPROM cells are erased.

17. The reconfigurable PLD of claim 15, wherein the first P-channel EEPROM cell and the NMOS transistor form an inverter with the first bit-line as an input and the output node as an output when the first P-channel EEPROM cell is erased while the second P-channel EEPROM cell is programmed.

18. The reconfigurable PLD of claim 15, wherein the second P-channel EEPROM cell and the NMOS transistor form an inverter with the second bit-line as an input and the output node as an output when the second P-channel EEPROM cell is erased while the first P-channel EEPROM cell is programmed.
